(19) United States
(12) Patent Application Publication
(10) Pub. No.: US 2005/0002161 A1
(43) Pub. Date: Jan. 6, 2005

(54) Heat dissipation device of serve

(75) Inventors: Kuei-Hua Chen, Taipei (TW); Chih-Peng Chuang, Taipei (TW)

Correspondence Address: BACON & THOMAS, PLLC, 625 SLATERS LANE, FOURTH FLOOR, ALEXANDRIA, VA, 22314, US

(73) Assignee: INVENTEC CORPORATION, Taipei (TW)

(21) Appl. No.: 10/610,582

(22) Filed: Jul. 2, 2003

(51) Int. Cl. H05K 7/20

(52) U.S. Cl. 361/687

(57) ABSTRACT

The present invention is to provide a heat dissipation device of a server comprising a first and a second heat dissipation units respectively mounted adjacent to a CPU and a power supply of the server for cooling the CPU and the power supply based on the temperatures thereof, wherein the current of air set up by the fans of the first and the second heat dissipation units can dissipate heat from the CPU and the power supply respectively without interfering heat generated by the CPU with heat generated by the power supply or vice verse. Thus, the heat dissipation of the CPU and the power supply will respectively be controlled in an easy and precise way.

### FIELD OF THE INVENTION

The present invention relates to heat dissipation devices and more particularly to a heat dissipation device (e.g., fan assembly) of server with improved characteristics.

### BACKGROUND OF THE INVENTION

Fan was invented long time ago. Fans are widely employed in many different fields due to the significant progress of electronic and network communication products. Further, features and customization of fans are gradually powerful and advanced respectively for meeting the demand of various electronic and network communication products. For example, an industrial server has a predetermined height of IU (IU=44.45 mm). It is understood that high heat can be generated from electronic components and CPU (central processing unit) of a server as they are running at high speed during operation. However, such high heat generated from electronic components cannot be effectively dissipated naturally due to the limited internal space of server. For solving this problem, conventionally, at least one fan is provided for cooling the server in order to lower the surface temperatures of the electronic components below an allowable maximum operating temperature. As a result, the server can operate normally.

The current heat dissipation arrangement of an industrial server is described below. A plurality of fans are disposed in a row at one end inside the server. A plurality of equally spaced openings are provided at each of two opposite ends of the server housing. The fans are operable in response to a control instruction from the control circuit of the heat dissipation arrangement. In operation, external air is drawn into the server from one end of the server housing prior to escaping from the other end thereof through the internal CPU and power supply. As such, temperature of each of the CPU and the power supply can be reduced below an operating temperature. Unfortunately, there is no physical separation between the CPU and the power supply in the prior heat dissipation arrangement of the server. As such, the single control circuit is unable to detect individual temperature of each of the CPU and the power supply for determining its heat dissipation efficiency. In fact, the control circuit is adapted to activate the fans as long as the internal temperature of the server exceeds the predetermined operating temperature. This can lower the heat dissipation efficiency of the server. To the worse, hot air cannot be effectively dissipated due to the interference of hot currents of air between the CPU and the power supply. As a result, temperature of either the CPU or the power supply may exceed the predetermined operating temperature, resulting in a malfunction or quick aging of the components thereof. Hence, a need for improvement exists.

### SUMMARY OF THE INVENTION

A primary object of the present invention is to provide a heat dissipation device of server. Based on required, respective heat dissipation capabilities of a CPU and a power supply of the server, the heat dissipation device comprises a first heat dissipation unit mounted adjacent to the CPU and a second heat dissipation unit mounted adjacent to the power supply. The first heat dissipation unit is adapted to control fans thereof for cooling the CPU based on temperature of the CPU. The second heat dissipation unit is adapted to control fans thereof for cooling the power supply based on temperature of the power supply. Current of air set up by the fans of the first heat dissipation unit and that set up by the fan of the second heat dissipation unit can dissipate heat from the CPU and the power supply respectively without interfering heat generated by the CPU with heat generated by the power supply or vice verse. Thus, it is possible of easily and precisely controlling heat dissipation of respective ones of the CPU and the power supply. By utilizing this, the above drawbacks of the prior art can be overcome. These drawbacks are that no physical separation between the CPU and the power supply in the well known heat dissipation arrangement of the server and lower heat dissipation efficiency of the server.

One object of the present invention is to provide a divider between the CPU and the power supply for physically separating hot currents of air between the CPU and the power supply, thereby preventing heat generated by the CPU from interfering with heat generated by the power supply or vice verse. As an end, the purpose of carrying out an independent heat dissipation of each of the CPU and the power supply can be obtained.

The above and other objects, features and advantages of the present invention will become apparent from the following detailed description taken with the accompanying drawings.

### BRIEF DESCRIPTION OF THE DRAWINGS

FIG. 1 is a perspective view of a preferred embodiment of heat dissipation device mounted in a server according to the invention.

### DETAILED DESCRIPTION OF THE PREFERRED EMBODIMENTS

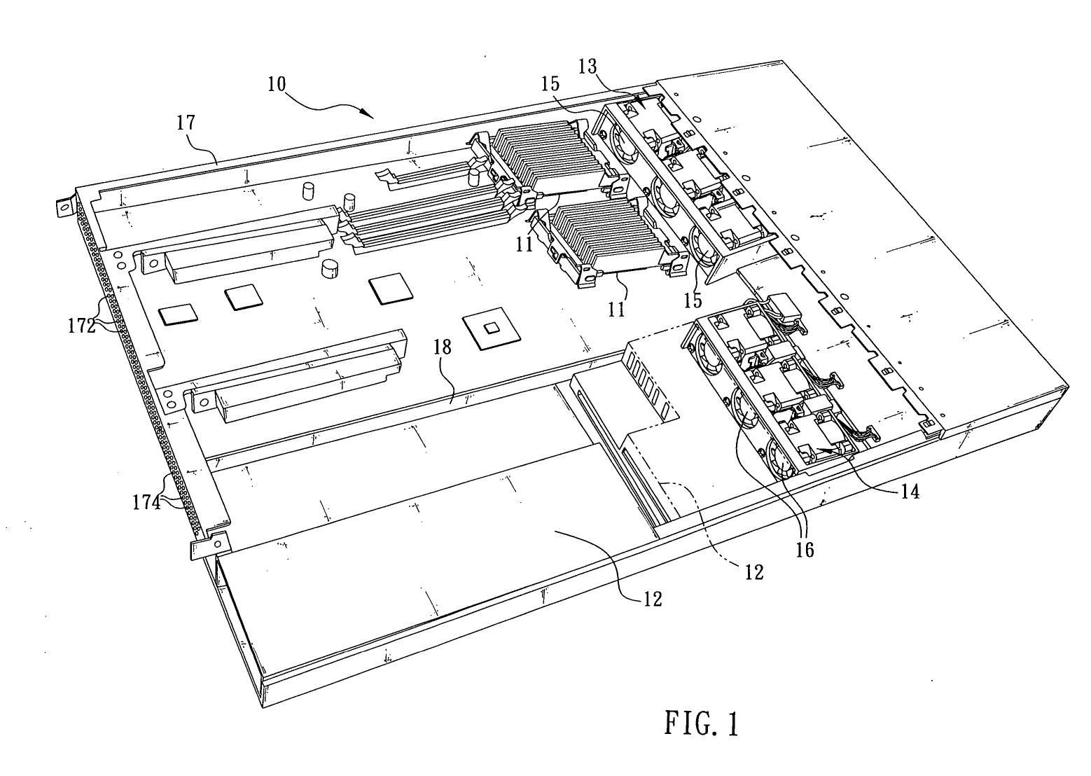

Referring to FIG. 1, there is shown a heat dissipation device mounted in a server 10 in accordance with the invention. Based on required, respective heat dissipation capabilities of a CPU 11 and a power supply 12 of the server 10, the heat dissipation device comprises a first heat dissipation unit 13 mounted adjacent to the CPU 11 and a second heat dissipation unit 14 mounted adjacent to the power supply 12. The first heat dissipation unit 13 comprises a heat sensor (not shown) on the CPU 11, one or a plurality of fans 15 at one side of the CPU 11, and a first control circuit (not shown) also at one side of the CPU 11. The first control circuit is adapted to control the fans 15 for cooling the CPU 11 based on temperature of the CPU 11 sensed by the heat sensor, thereby maintaining the temperature of the CPU 11 below a predetermined operating temperature. Similarly, the second heat dissipation unit 14 comprises a heat sensor (not shown) on the power supply 12, one or a plurality of fans 16 at one side of the power supply 12, and a second control circuit (not shown) also at one side of the power supply 12. The second control circuit is adapted to control the fans 16 for cooling the power supply 12 based on temperature of the power supply 12 sensed by the heat sensor, thereby maintaining the temperature of the power supply 12 below a predetermined operating temperature.

Referring to FIG. 1 again, by configuring as above, the first heat dissipation unit 13 can control heat dissipation of the CPU 11 based on heat generated by the CPU 11 and the second heat dissipation unit 14 can control heat dissipation of the power supply 12 based on heat generated by the power supply 12 respectively. This can carry out respective heat dissipation of either the CPU 11 or the power supply 12 for preventing heat generated by the CPU 11 from interfering with heat generated by the power supply 12 or vice verse. As an end, the purpose of easily and precisely controlling heat dissipation of respective ones of the CPU 11 and the power supply 12 is achieved.

Referring to FIG. 1 again, in the invention a plurality of equally spaced openings (not shown) are provided in rows on a housing 17 of the server 10 adjacent to one end of the CPU 11. Correspondingly, a plurality of equally spaced openings 172 are provided in rows on the housing 17 opposite the other end of the CPU 11. In an operation of dissipating heat from the first heat dissipation unit 13, external air is drawn into the server 10 from one end of the housing 17 by the fans 15 of the first heat dissipation unit 13 prior to escaping from the other end of the housing 17 through the CPU 11. As such, temperature of the CPU 11 can be reduced below the predetermined operating temperature by the air suction of the fans 15.

Referring to FIG. 1 again, in the invention a plurality of equally spaced openings (not shown) are provided in rows on the housing 17 of the server 10 adjacent to one end of the power supply 12. Correspondingly, a plurality of equally spaced openings 174 are provided in rows on the housing 17 opposite the other end of the power supply 12. In an operation of dissipating heat from the second heat dissipation unit 14, external air is drawn into the server 10 from one end of the housing 17 by the fans 16 of the second heat dissipation unit 14 prior to escaping from the other end of the housing 17 through the power supply 12. As such, temperature of the power supply 12 can be reduced below the predetermined operating temperature by the air suction of the fans 16.

Referring to FIG. 1 again, in the invention a divider 18 is provided between the CPU 11 and the power supply 12 for physically separating hot currents of air between the CPU 11 and the power supply 12, thereby preventing heat generated by the CPU 11 from interfering with heat generated by the power supply 12 or vice verse. As an end, the purpose of carrying out an independent heat dissipation of each of the CPU 11 and the power supply 12 can be obtained.

In brief, the heat dissipation device of the server 10 comprises a first heat dissipation unit 13 associated with the CPU 11 and a second heat dissipation unit 14 associated with the power supply 12. The first heat dissipation unit 13 and the second heat dissipation unit 14 are substantially two independent heat dissipation assemblies. As such, it is possible of customizing the numbers and powers of the fans 15 and 16 of the first heat dissipation unit 13 and the second heat dissipation unit 14 based on the required, respective heat dissipation capabilities of the CPU 11 and the power supply 12 respectively. As a result, precise heat dissipation and high efficiency can be carried out. At the same time, current of air set up by the fans 15 of the first heat dissipation unit 13 and that set up by the fan 16 of the second heat dissipation unit 14 can dissipate heat from the CPU 11 and the power supply 12 respectively without interfering heat generated by the CPU 11 with heat generated by the power supply 12 or vice verse. As an end, the purpose of easily and precisely controlling heat dissipation of respective ones of the CPU 11 and the power supply 12 is achieved.

While the invention has been described by means of specific embodiments, numerous modifications and variations could be made thereto by those skilled in the art without departing from the scope and spirit of the invention set forth in the claims.

1. A heat dissipation device of a server, comprising:
a first heat dissipation unit mounted adjacent to a CPU of the server, the first heat dissipation unit comprising a first heat sensor on the CPU, one or more first fans at one side of the CPU, and a first control circuit at one side of the CPU, the first control circuit being adapted to control the second fans for cooling the CPU based on temperature of the CPU sensed by the first heat sensor so as to maintain the temperature of the CPU below a predetermined operating temperature; and
a second heat dissipation unit mounted adjacent to the power supply, the second heat dissipation unit comprising a second heat sensor on a power supply of the server, a plurality of second fans at one side of the power supply, and a second control circuit at one side of the power supply, the second control circuit being adapted to control the second fans for cooling the power supply based on temperature of the power supply sensed by the second heat sensor so as to maintain the temperature of the power supply below the predetermined operating temperature.

2. The heat dissipation device of claim 1, further comprising a plurality of equally spaced first openings disposed in rows on a housing of the server adjacent to one end of the CPU and a plurality of equally spaced second openings disposed in rows on the housing opposite the other end of the CPU, and wherein in an operation of dissipating heat from the first heat dissipation unit, air is drawn into the server from one end of the housing by the first fans of the first heat dissipation unit prior to escaping from the other end of the housing through the CPU so that the temperature of the CPU can be reduced below the predetermined operating temperature by the first fans.

3. The heat dissipation device of claim 2, further comprising a plurality of equally spaced third openings disposed in rows on the housing adjacent to one end of the power supply and a plurality of equally spaced fourth openings disposed in rows on the housing opposite the other end of the power supply, and wherein in an operation of dissipating heat from the second heat dissipation unit, air is drawn into the server from one end of the housing by the second fans of the second heat dissipation unit prior to escaping from the other end of the housing through the power supply so that the temperature of the power supply can be reduced below the predetermined operating temperature by the second fans.

4. The heat dissipation device of claim 3, further comprising a divider disposed between the CPU and the power supply for separating hot currents of air between the CPU and the power supply and either preventing heat generated by the CPU from interfering with heat generated by the power supply or preventing heat generated by the power supply from interfering with heat generated by the CPU.
